(19) United States
(12) Patent Application Publication
(10) Pub. No.: US 2025/0360618 A1
(43) Pub. Date: Nov. 27, 2025

(54) ROBOT TEACHING SYSTEM AND ROBOT CONTROL DEVICE

(71) Applicant: DAIHEN CORPORATION, Osaka (JP)

(72) Inventors: Masaaki HIJIKATA, Osaka (JP); Toyokazu Kitano, Osaka (JP); Kentaro Okamoto, Osaka (JP); Daisuke Sado, Osaka (JP)

(73) Assignee: DAIHEN CORPORATION, Osaka (JP)

(21) Appl. No.: 19/216,367

(22) Filed: May 22, 2025

(30) Foreign Application Priority Data
May 27, 2024 (JP) 2024-085517

(51) Int. Cl. B25J 9/16

(52) U.S. Cl. CPC B25J 9/163; B25J 9/1653; B25J 9/1661

(57) ABSTRACT

To provide a robot teaching system and a robot control device capable of appropriately generating a work program for moving a transfer robot to a target position in a chamber in a flat panel manufacturing system for manufacturing a flat panel. A robot teaching system includes feature point detection unit that detects a feature point in a chamber while sensing inside of the chamber by using a sensor installed in a holding portion that holds the workpiece in a transfer robot, position calculation unit that calculating a position of the feature point, and program generation unit that generates a work program for operating the transfer robot to be moved to a target position based on the position of the feature point.

### BACKGROUND

### Field

The present invention relates to a robot teaching system and a robot control device.

### Description of Related Art

In recent years, many industrial robots have become widespread in the industry. There are large manufacturing systems for performing treatment on glass substrates for large flat panels, including flat panel displays (FPDs) such as liquid crystal displays and organic EL displays.

In such a large manufacturing system, a plurality of process chambers

corresponding to respective steps of treatment are disposed in order to perform various steps of treatment on a workpiece such as a glass substrate. A transfer robot (transfer device) is disposed in a transfer chamber, and the workpiece is transferred to a desired position in each process chamber by the transfer robot (transfer device).

In Patent Publication JP-A 2019-220588, a transfer device includes an optical sensor at a tip of a support pick and specifies an upper end position of an opening between a transfer chamber and a load lock chamber by emitting light in the tip direction while moving the support pick upward in the transfer chamber. Also, in the load lock chamber, an upper end position/sidewall position of a buffer (groove) is specified by emitting light in the tip direction/down direction while moving the support pick upward/rotationally. The operation of the transfer device is then corrected on the basis of the specified upper end position of the opening or the specified upper end position/sidewall position of the buffer (groove). As described above, in Patent Publication JP-A 2019-220588, adjustment of an operation position of the transfer device is automatically performed.

### SUMMARY

However, the transfer device disclosed in Patent Publication JP-A 2019-220588 may collide with the upper end position/sidewall position of a specific buffer (groove) since the transfer robot checks the upper end position/sidewall position as it is rotating within the chamber, and, because this is local detection, may not allow the entire interior of the chamber to be conceived. If other obstacles are present in the chamber, the transfer device may collide with the obstacles.

A large manufacturing system for performing treatment on glass substrates for large flat panels has a problem that it is difficult for an operator to directly check a state of the interior of a chamber to operate a transfer robot.

Therefore, an object of the present invention is to provide a robot teaching system and a robot control device that can appropriately generate a work program for moving a transfer robot to a target position in a chamber in a flat panel manufacturing system for manufacturing a flat panel.

According to an aspect of the present invention, there is provided a robot teaching system including a plurality of chambers, a transfer robot that transfers a workpiece between the plurality of chambers, and a robot control device that controls an operation of the transfer robot, and used in a flat panel manufacturing system that manufactures a flat panel, the robot teaching system including feature point detection unit that detects a feature point in a chamber while sensing the inside of the chamber by using a sensor installed in a holding portion that holds the workpiece in the transfer robot; position calculation unit that calculates a position of the feature point; and program generation unit that generates a work program for operating the transfer robot to be moved to a target position based on the position of the feature point.

According to this aspect, the feature point detection unit detects the feature point in the chamber by using the sensor installed in the holding portion of the transfer robot, and the program generation unit generates the work program for operating the transfer robot to be moved to the target position based on the position of the feature point calculated by the position calculation unit. Thus, it is possible to ascertain a state of the inside of the chamber and to appropriately generate the work program for moving the transfer robot to the target position in the chamber.

In the above aspect, the feature point may include at least a part of a support pin that supports the workpiece in the chamber.

According to this aspect, it is possible to ascertain the position of the support pin disposed in the chamber, and to appropriately generate the work program for moving the transfer robot on the basis of the position of the support pin.

In the above aspect, the feature point may include at least a part of a wall surface configuring the chamber.

According to this aspect, it is possible to ascertain the position of the wall surface configuring the chamber and to appropriately generate the work program for moving the transfer robot on the basis of the position of the wall surface.

In the above aspect, an operation path of the transfer robot may be set to avoid a collision in the chamber in the work program.

According to this aspect, the transfer robot can be appropriately moved in the chamber on the basis of the work program.

In the above aspect, the robot teaching system may further include mapping unit that maps the position of the feature point in the chamber and display unit that displays a result of the mapping.

According to this aspect, since the mapping unit maps the position of the feature point in the chamber and the display unit displays the result of the mapping, a user can check a state in the chamber.

In the above aspect, the robot teaching system may further include target position receiving unit that receives a method of setting the target position through a user operation.

According to this aspect, the target position receiving unit can set a target position corresponding to each user because target position receiving unit receives how to set a target position through a user operation.

According to another aspect of the present invention, there is provided a robot control device that is used in a flat panel manufacturing system for manufacturing a flat panel and controls an operation of a transfer robot that transfers a workpiece between a plurality of chambers, the robot control device including feature point detection unit that detects a feature point in a chamber while sensing the inside of the chamber by using a sensor installed in a holding portion that holds the workpiece in the transfer robot; position calculation unit that calculates a position of the feature point; and program generation unit that generates a work program for operating the transfer robot to be moved to a target position based on the position of the feature point.

According to this aspect, the feature point detection unit detects the feature point in the chamber by using the sensor installed in the holding portion of the transfer robot, and the program generation unit generates the work program for operating the transfer robot to be moved to the target position based on the position of the feature point calculated by the position calculation unit. Thus, it is possible to ascertain a state of the inside of the chamber and to appropriately generate the work program for moving the transfer robot to the target position in the chamber.

According to the present invention, it is possible to provide a robot teaching system and a robot control device that can appropriately generate a work program for moving a transfer robot to a target position in a chamber in a flat panel manufacturing system for manufacturing a flat panel.

### BRIEF DESCRIPTION OF DRAWINGS

FIG. 1 is an external perspective view illustrating an outline of a flat panel manufacturing system 1 according to an embodiment of the present invention;

FIG. 2 is a plan view illustrating an internal structure of the flat panel manufacturing system 1 according to the embodiment of the present invention;

FIG. 3 is a schematic diagram illustrating a configuration of a transfer robot system 10 used in the flat panel manufacturing system 1 according to the embodiment of the present invention;

FIG. 4A is a schematic diagram illustrating a state in which a sensor device 30 (wall surface sensing) is disposed on a transfer robot 20 used in the flat panel manufacturing system 1 according to the embodiment of the present invention;

FIG. 4B is a schematic diagram illustrating a state in which the sensor device 30 (advancing direction sensing) is disposed on the transfer robot 20 used in the flat panel manufacturing system 1 according to the embodiment of the present invention;

FIG. 4C is a schematic diagram illustrating a state in which the sensor device 30 (downward sensing) is disposed on the transfer robot 20 used in the flat panel manufacturing system 1 according to the embodiment of the present invention;

FIG. 5 is a functional block diagram illustrating each function of a robot control device 100 that controls an operation of the transfer robot 20 in a robot teaching system 11 used in the flat panel manufacturing system 1 according to the embodiment of the present invention;

FIG. 6 is a schematic diagram illustrating a state in which the transfer robot 20 senses a sidewall surface and a support pin 90 in a process chamber PC while entering the process chamber PC from a transfer chamber TC; and

FIG. 7 is a flow chart illustrating a flow of processing of a robot teaching method M100 executed by the robot teaching system 11 used in the flat panel manufacturing system 1 according to the embodiment of the present invention.

### DETAILED DESCRIPTION

Embodiments of the present invention will now be described in detail with reference to the accompanying drawings. Note that the embodiments described below are merely specific examples for carrying out the present invention, and are not intended to limit the present invention. Also, for better understanding of the description, the same constituents in the drawings may be denoted by the same reference numerals as much as possible, and redundant descriptions may be omitted.

### One Embodiment

### Configuration of Flat Panel Manufacturing System

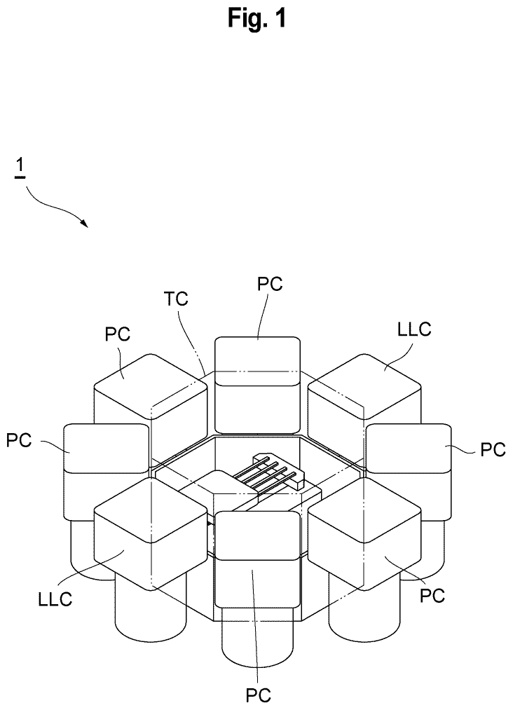

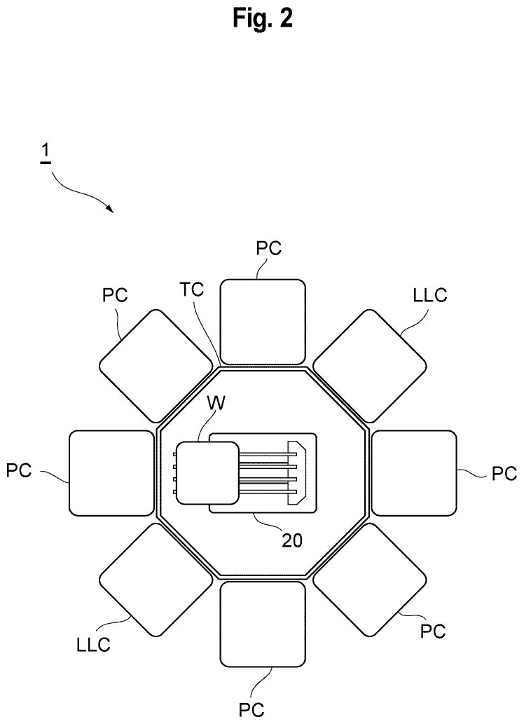

FIG. 1 is an external perspective view illustrating an outline of a flat panel manufacturing system 1 according to an embodiment of the present invention, and FIG. 2 is a plan view illustrating an internal structure of the flat panel manufacturing system 1 according to the embodiment of the present invention. As illustrated in FIGS. 1 and 2, the flat panel manufacturing system 1 is a large multi-chamber system including a transfer chamber TC at the center and a plurality of process chambers PC and load lock chambers LLC disposed to surround the transfer chamber TC.

The flat panel manufacturing system 1 is a vacuum treatment system for performing treatment on glass substrates for large flat panels including flat panel displays (FPDs) such as liquid crystal displays and organic EL displays.

The load lock chamber LLC is a chamber for taking in and out a workpiece W (e.g., a glass substrate) to and from the outside before and after treatment in the plurality of process chambers PC, so that the plurality of process chambers PC can be maintained in a vacuum state without being opened to an external atmospheric atmosphere. Note that the transfer chamber TC can also be maintained in a vacuum state.

The transfer chamber TC is configured to be maintained in a vacuum state as described above, and the transfer robot 20 is disposed therein. The transfer robot 20 has a transfer mechanism (a hand holder or a finger) for transferring the workpiece W between each process chamber PC and the load lock chamber LLC.

The plurality of process chambers PC are configured to be maintained in a vacuum state as described above, and each include a placement table on which the workpiece W transferred by the transfer robot 20 disposed in the transfer chamber TC is placed. The placement table may be provided with, for example, a plurality of support pins, and configured to be supported by the support pins to place the workpiece W thereon. In each process chamber PC, plasma treatment such as chemical vapor deposition (CVD), etching treatment, ashing treatment, and film formation treatment under vacuum may be performed on the workpiece W in a state in which the workpiece W is placed. In each process chamber PC, the same kind of treatment may be performed, or different kinds of treatment may be performed for each process chamber.

### Configuration of Transfer Robot System

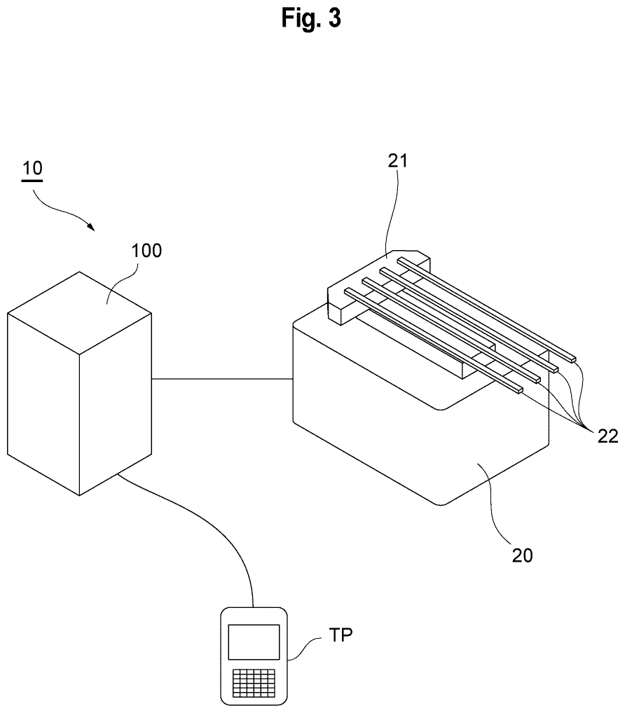

FIG. 3 is a schematic diagram illustrating a configuration of a transfer robot system 10 used in the flat panel manufacturing system 1 according to the embodiment of the present invention. As illustrated in FIG. 3, the transfer robot system 10 includes a transfer robot 20, a robot control device 100, and a teaching pendant TP.

As described with reference to FIGS. 1 and 2, the transfer robot 20 is disposed in the transfer chamber TC in the flat panel manufacturing system 1, and transfers the workpiece W between each of the process chambers PC and the load lock chamber LLC. The transfer robot 20 is, for example, a horizontal multi-joint robot for transferring glass substrates, and is a clean transfer robot used for transfer in clean environments such as manufacturing environments of semiconductor devices and flat panel displays and medical/food industries. In the present embodiment, the transfer robot 20 is, for example, of a two-axis or three-axis cylindrical coordinate type and has a hand holder 21 and fingers (holding portion) 22 as end effectors, and a description will now be made of an example of transferring the workpiece W in a state in which the workpiece W (for example, a glass substrate) is held by the fingers 22.

The robot control device 100 is a device that controls an operation of the transfer robot 20. For example, the robot control device 100 is connected to an operation device such as the teaching pendant TP, and can acquire operation instruction information input in the operation device. The robot control device 100 starts and stops the transfer robot 20, or operates each shaft, each arm, and the hand holder 21 (finger 22) of the transfer robot 20 to take out, transfer, and install the workpiece W in each process chamber PC and the load lock chamber LLC, on the basis of the operation instruction information.

The teaching pendant TP is an operation device operated by an operator, and receives an input from the operator about transfer work for transferring the workpiece W with respect to the operation instruction information for the transfer robot 20. Typically, the operator inputs appropriate instruction information by using an operation device such as the teaching pendant TP for, for example, start and stop of the transfer robot 20, and settings for the transfer robot 20, an operation of the arm and the hand holder 21 (fingers 22), registration of teaching points, and the like.

For registration of teaching points, the operator may sequentially register the teaching points on an operation path by using an operating device such as the teaching pendant TP while operating the transfer robot 20, or may automatically register the teaching points in automatic teaching. Automatic teaching is effective in environments and situations such as the flat panel manufacturing system 1 in which an operator cannot enter the inside and cannot ascertain a state of the inside of each chamber from the outside.

Here, there is a situation in which the transfer robot 20 installed in the transfer chamber TC moves the fingers 22 into the load lock chamber LLC, takes out the workpiece W disposed therein with the fingers 22, and transfers the workpiece W to the placement table in the process chamber PC while holding the workpiece W with the fingers 22. The transfer robot 20 operates the arm and the hand holder 21 (fingers 22) on the basis of the operation instruction information from the robot control device 100, takes out the workpiece W from the load lock chamber LLC, and transfers the workpiece W to the process chamber PC that is a destination of the workpiece W.

In this case, the fingers 22 holding the workpiece W enter the load lock chamber LLC or the process chamber PC from the transfer chamber TC and are advanced inside the load lock chamber LLC or the process chamber PC.

For example, the fingers 22 attached to the hand holder 21 of the transfer robot 20 advance while avoiding collision with a support pin or a wall surface disposed in the transfer chamber TC or the process chamber PC, and transfer the workpiece W held by the fingers 22 to a target position.

As described above, since it is difficult for the operator to operate the transfer robot while directly checking a state of the inside of each chamber, it is necessary for the operator to teach the flat panel manufacturing system 1 such that, for example, a sensor device disposed on the fingers 22 is used to properly ascertain a state of the inside of each chamber and move the transfer robot 20 to a target position. Hereinafter, a method of generating a work program for operating the transfer robot 20 while causing the fingers 22 to enter the load lock chamber LLC and the process chamber PC and ascertaining a state of the inside of the chamber by using the sensor device will be described.

### Configuration of Sensor Device

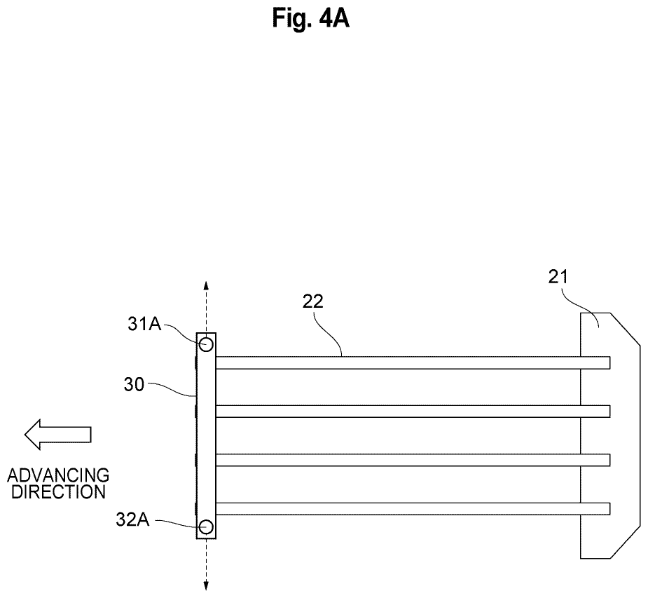

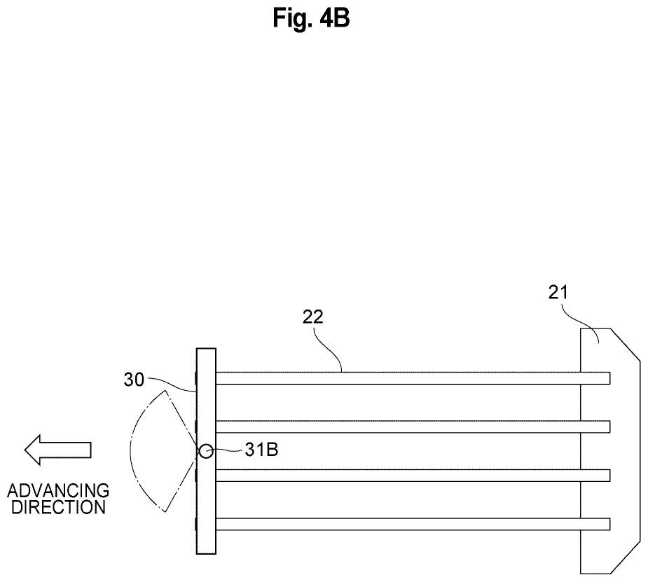

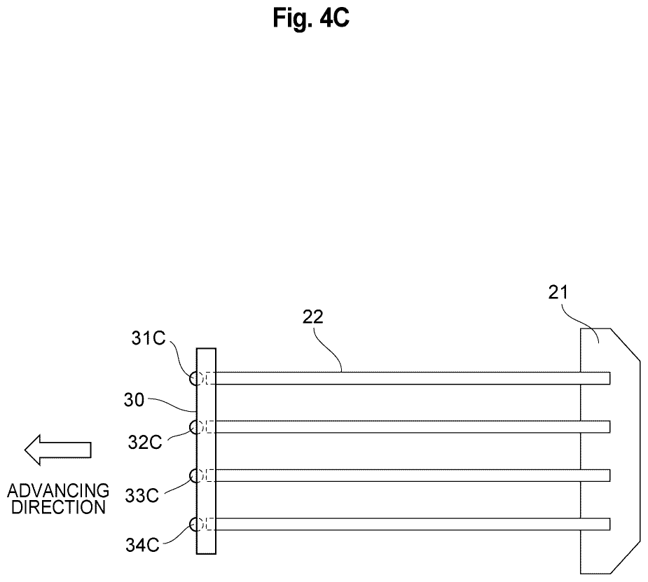

FIG. 4A is a schematic diagram illustrating a state in which the sensor device 30 (wall surface sensing) is disposed on the transfer robot 20 used in the flat panel manufacturing system 1 according to the embodiment of the present invention. As illustrated in FIG. 4A, the sensor device 30 is disposed at the tip of the fingers 22 attached to the hand holder 21 of the transfer robot 20.

The sensor device 30 is provided with two sensors 31A and 32A at both ends thereof. For example, the two sensors 31A and 32A are may be attached to a front surface, a rear surface, a surface on the advancing direction side, a surface on the hand holder 21 side, or an outer side surface of the sensor device 30.

The sensor device 30 to which the two sensors 31A and 32A are attached is placed and held at the tip of the fingers 22 of the transfer robot 20, and can sense the outside direction with the two sensors 31A and 32A. Specifically, the two sensors 31A and 32A may be distance measuring sensors capable of sensing a distance from both ends to the wall surface in the outside direction in a direction orthogonal to the advancing direction of the fingers 22 and in the horizontal direction.

Thus, the distance from the sensor 31A to the wall surface in the outside direction and the distance from the sensor 32A to the wall surface in the outside direction can be sensed. That is, since the two sensors 31A and 32A are installed at both ends of the sensor device 30, it is possible to ascertain the distance from each end of the tip of the fingers 22 to the wall surface.

Note that positions of the sensors 31A and 32A installed in the sensor device 30 are not limited to both ends of the sensor device 30, and for example, one sensor may be installed at one end or the center of the sensor device 30. A distance from the one sensor to the wall surface may be sensed, and a distance from both ends of the tip of the fingers 22 to the wall surface may be calculated on the basis of the sensing result and a size of the load lock chamber LLC (process chamber PC).

The sensor device 30 may include a sensor capable of sensing the advancing direction to sense a distance to the back wall surface in the advancing direction. Specifically, the sensor device 30 may include a distance measuring sensor capable of sensing a distance to the wall surface (back wall surface) in the advancing direction and the horizontal direction of the fingers 22, and may ascertain the distance to the back wall surface.

FIG. 4B is a schematic diagram illustrating a state in which the sensor device 30 (advancing direction sensing) is disposed in the transfer robot 20 used in the flat panel manufacturing system 1 according to the embodiment of the present invention. As illustrated in FIG. 4B, the sensor device 30 is disposed at the tip of the fingers 22 attached to the hand holder 21 of the transfer robot 20.

The sensor device 30 includes a sensor 31B. For example, the sensor 31B may be a two-dimensional laser sensor that is attached to the front surface, the rear surface, or the side surface on the advancing direction side of the sensor device 30 and can sense only a predetermined range in the direction orthogonal to the advancing direction of the fingers 22 of the transfer robot 20.

The sensor device 30 to which the sensor 31B is attached is placed and held at the tip of the fingers 22 of the transfer robot 20, and is configured to be able to sense the advancing direction of the fingers 22 of the transfer robot 20 and the lower direction inside the load lock chamber LLC and the process chamber PC with the sensor 31B.

As a result, while the fingers 22 enter the load lock chamber LLC and the process chamber PC, the sensor 31B can sequentially sense the lower direction inside the load lock chamber LLC and the process chamber PC in the above predetermined range (sensing range) in the two-dimensional laser sensor, and can detect the support pins and the like.

Note that, one sensor 31B is disposed at the center of the sensor device 30, but the present invention is not limited thereto. For example, a sensor may be disposed at an end of the sensor device 30 or two or more sensors may be disposed as long as the support pins or the like disposed inside the load lock chamber LLC and the process chamber PC can be detected and its positions can be ascertained.

FIG. 4C is a schematic diagram illustrating a state in which the sensor device 30 (downward sensing) is disposed in the transfer robot 20 used in the flat panel manufacturing system 1 according to the embodiment of the present invention. As illustrated in FIG. 4C, the sensor device 30 is disposed at the tip of the fingers 22 attached to the hand holder 21 of the transfer robot 20. The sensor device 30 includes four sensors 31C to 34C, and the sensors 31C to 34C are disposed to respectively correspond to the four fingers 22.

The four sensors 31C to 34C included in the sensor device 30 are attached to the rear surface of the sensor device 30 to be disposed to respectively correspond to the four fingers 22, for example. The sensor device 30 is placed and held on the tip of the fingers 22 of the transfer robot 20, so that the sensors 31C to 34C can sense the down direction of the four fingers 22, respectively.

As a result, while the fingers 22 enter the load lock chamber LLC and the process chamber PC, each of the sensors 31C to 34C can detect whether support pins or the like are disposed in the down direction of each of the four fingers 22.

Note that attachment positions of the four sensors 31C to 34C in the sensor device 30 are not limited to the rear surface of the sensor device 30, and other attachment positions or attachment methods may be used as long as the down direction of each of the four fingers 22 can be sensed. For example, the four sensors 31C to 34C may be fixed to the sensor device 30 downward by using a fitting or the like that is disposed to protrude from the tip of the fingers 22 in the advancing direction of the fingers 22.

The sensor devices 30 illustrated in FIGS. 4A to 4C are each disposed at the tip of the fingers 22 of the transfer robot 20, but the sensor device 30 (including each sensor disposed in the sensor device 30) is calibrated, and the robot control device 100 ascertains the position of the sensor device 30 (the position of each sensor disposed in the sensor device 30), and can also ascertain positions of the wall surface and the support pins sensed by the sensor device 30 (each sensor disposed in the sensor device 30) from the positions of the fingers 22 (robot coordinate system).

Here, the sensor device 30 includes one or more sensors and is disposed as a unit at the tip of the fingers 22 of the transfer robot 20, but is not limited thereto. As long as the positions of the wall surface and the support pin can be appropriately ascertained, for example, one or more sensors (sensor device) may be attached to the tip of the fingers 22 directly or via an attachment mechanism or the like. The robot control device 100 ascertains a configuration and a position of the attachment mechanism in advance, and can also ascertain the positions of the wall surface and of the support pins detected by the sensors (sensor device) (robot coordinate system). In this case, the above-described calibration may be omitted.

The sensor devices 30 illustrated in FIGS. 4A to 4C respectively include the sensors 31A and 32A for wall surface sensing, the sensor 31B for support pin sensing in the advancing direction/the lower direction, and the sensors 31C to 34C for sensing the presence or absence of a support pin in the down direction. However, two or more of these sensors may be combined.

Note that sensors installed in the sensor device 30 are not limited to a distance measuring sensor and a two-dimensional laser sensor, and may be, for example, a camera (stereo camera), a LiDAR, and other optical sensors.

The sensor device 30 may include a control unit, a communication unit, and the like, and notifies the robot control device 100 of information detected (acquired) by one or more sensors disposed in the sensor device 30, for example.

### Configuration of Robot Control Device

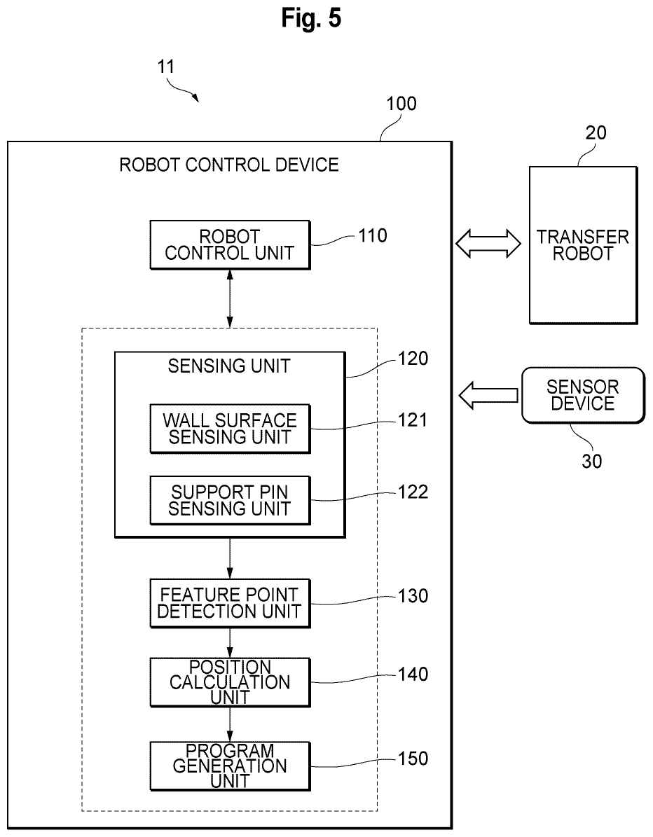

FIG. 5 is a functional block diagram illustrating each function of the robot control device 100 that controls an operation of the transfer robot 20 in a robot teaching system 11 used in the flat panel manufacturing system 1 according to the embodiment of the present invention. As illustrated in FIG. 5, the robot control device 100 includes robot control unit 110, sensing unit 120, feature point detection unit 130, position calculation unit 140, and program generation unit 150, and controls the operation of the transfer robot 20.

The robot control device 100 senses a feature point inside the load lock chamber LLC (process chamber PC) with the sensor of the sensor device 30 while causing the hand holder 21 (fingers 22) to enter the load lock chamber LLC (process chamber PC) from the transfer chamber TC in a state in which the sensor device 30 is held at the tip of the fingers 22.

As described with reference to FIG. 3, the robot control device 100 is connected to the transfer robot 20, and further has many functions to perform various types of control on the basis of operation instruction information from an operation device such as the teaching pendant TP, automatic control (automatic teaching), or the like, and performs processing. Here, the robot control device 100 is mainly described as having the function of appropriately ascertaining a state of the transfer robot 20 in the load lock chamber LLC (process chamber PC) and teaching the transfer robot 20 to be moved to a target position, but has other configurations and functions.

The robot control unit 110 operates the transfer robot 20. For example, the transfer robot 20 holds the sensor device 30 via the fingers 22, and the robot control unit 110 operates each shaft, each arm, and the hand holder 21 (fingers 22) of the transfer robot 20.

The sensing unit 120 senses the inside of the load lock chamber LLC (process chamber PC) with the sensor of the sensor device 30 while causing the hand holder 21 (fingers 22: holding portion) of the transfer robot 20 to enter the load lock chamber LLC (process chamber PC) from the transfer chamber TC by using the robot control unit 110.

For example, the sensing unit 120 includes wall surface sensing unit 121 and support pin sensing unit 122. The wall surface sensing unit 121 senses a distance to the wall surface inside the load lock chamber LLC (process chamber PC) by using the sensors 31A and 32A (FIG. 4A) attached to the sensor device 30. The support pin sensing unit 122 senses the lower direction of the advancing direction of the fingers 22 and senses the down direction of each of the four fingers 22 inside the load lock chamber LLC (process chamber PC) by using the sensor 31B (FIG. 4B) and/or the sensors 31C to 34C (FIG. 4C) attached to the sensor device 30.

The feature point detection unit 130 detects a feature point in the load lock chamber LLC (process chamber PC) while sensing the inside of the load lock chamber LLC (process chamber PC) by using the sensor device 30 held by the fingers 22 of the transfer robot 20.

For example, when the wall surface sensing unit 121 is sensing the sidewall surface of the load lock chamber LLC (process chamber PC), the feature point detection unit 130 may detect, for example, each point of the sidewall surface sensed at every predetermined timing as a feature point. When the support pin sensing unit 122 is sensing the lower direction of the advancing direction of the fingers 22 inside the load lock chamber LLC (process chamber PC) and/or the down direction of each of the four fingers 22, the feature point detection unit 130 may detect, for example, a support pin or another obstacle as a feature point.

More specifically, in a case where the sensor installed in the sensor device 30 is a camera, the feature point detection unit 130 may detect a support pin, another obstacle, or the like through pattern matching or the like on the basis of an acquired image. In a case where the sensor is an optical sensor such as a distance measuring sensor, the feature point detection unit 130 may detect a support pin, another obstacle, or the like on the basis of a distance (displacement) from the sensor to a bottom surface inside the load lock chamber LLC (process chamber PC).

The position calculation unit 140 calculates a position of the feature point detected by the feature point detection unit 130. As described above, the robot control device 100 ascertains in advance the position of the sensor device 30 (including the sensor installed in the sensor device 30) disposed at the tip of the fingers 22 through calibration or the like. As a result, for example, the position calculation unit 140 may calculate the position (robot coordinates) of the feature point detected by the sensing unit 120 and the feature point detection unit 130 on the basis of the position (robot coordinates) of the sensor device 30.

Specifically, the position calculation unit 140 calculates a position (robot coordinates) of the sidewall surface of the load lock chamber LLC (process chamber PC) and a position (robot coordinates) of the support pin, another obstacle, or the like inside the load lock chamber LLC (process chamber PC).

The program generation unit 150 generates a work program for operating the transfer robot 20 to be moved to a target position based on the position of the feature point detected by the feature point detection unit 130. As described above, since the robot control device 100 ascertains the position (robot coordinates) of the sidewall surface of the load lock chamber LLC (process chamber PC) and the position (robot coordinates) of the support pin and another obstacle inside the load lock chamber LLC (process chamber PC), an operation of the transfer robot 20 including an operation path of the transfer robot is set in the work program so that the transfer robot 20 (including the fingers 22 and the workpiece W held by the fingers) reaches the target position while avoiding a collision with the wall surface, the support pin, another obstacle, or the like.

Here, the target position may be set, for example, at the center of the load lock chamber LLC (process chamber PC). The center position may be calculated on the basis of the positions of the wall surface and/or the support pin calculated by the feature point detection unit 130 and the position calculation unit 140. An operation of the transfer robot 20 including the operation path of the transfer robot 20 may be set in the work program such that a tool center point (TCP) of the transfer robot 20 reaches the target position. The TCP is a center position of a region of the fingers 22 where the workpiece W is placed when the workpiece W (flat panel) is placed on the hand (fingers 22). For example, when the workpiece W is placed on the whole fingers 22, the TCP is a center position of the fingers 22, and when the workpiece W is placed on a half of the tip side of the fingers 22, the TCP is a center position of a region of a half of the tip side of the fingers 22 (that is, a ¼ position of the fingers 22).

Note that the target position is not limited to the center of the load lock chamber LLC (process chamber PC), and an appropriate position may be set according to treatment in each chamber, or may be set by an operator (target position receiving unit). For example, as the target position receiving unit, the operator may specifically set the target position by using the teaching pendant TP or the like, may set the center, the far side, the near side, or the like as the target position with reference to the position of the wall surface of the chamber calculated by the feature point detection unit 130 and the position calculation unit 140, or may set the center, the far side, the near side, or the like as the target position with reference to a support pin at each end among the support pins calculated by the feature point detection unit 130 and the position calculation unit 140. A center support pin or any number of support pins may be set as the target position.

On the basis of the position of the sidewall surface of the load lock chamber LLC (process chamber PC) calculated by the feature point detection unit 130 and the position calculation unit 140 and the position of the support pin, another obstacle, or the like inside the load lock chamber LLC (process chamber PC), the positions may be mapped in the robot coordinate system (mapping unit), and the mapping result may be displayed on a display screen of the teaching pendant TP (display unit) or the like.

As a result, the operator can ascertain a state of the inside of the load lock chamber LLC (process chamber PC). When an image of the transfer robot 20 (fingers 22) is also superimposed, a state of the inside of the load lock chamber LLC (process chamber PC) can be more appropriately ascertained. The operator may set the target position after checking the display screen. By mapping the position of the sidewall surface of the load lock chamber LLC (process chamber PC) and the support pin, another obstacle, or the like inside the load lock chamber LLC (process chamber PC), a possibility that the transfer robot 20 (including the fingers 22 and the workpiece W placed thereon) collides with the sidewall surface, the support pins, other obstacles, and the like can be reduced compared with a case where the operation of the transfer robot 20 is simply taught such that the TCP reaches a target position.

### Operation of Transfer Robot

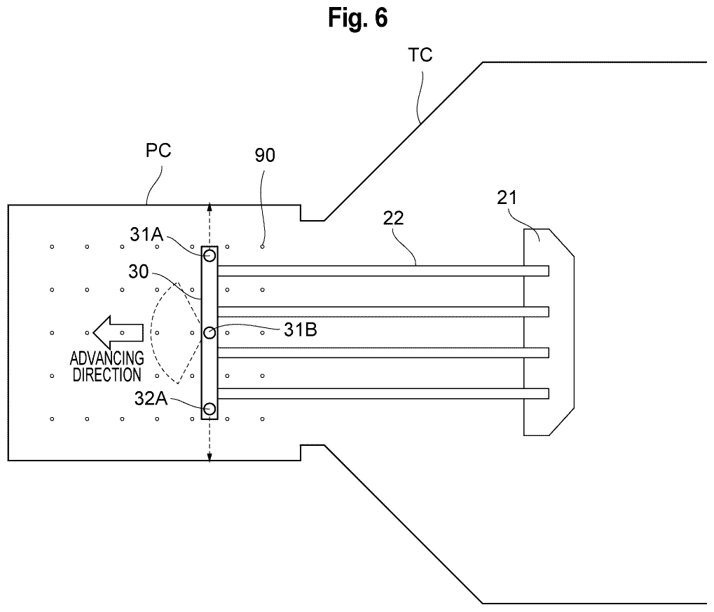

FIG. 6 is a schematic diagram illustrating a state in which the transfer robot 20 senses the sidewall surface and the support pin 90 in the process chamber PC while entering the process chamber PC from the transfer chamber TC. As illustrated in FIG. 6, the sensor device 30 includes two sensors 31A and 32A at both ends thereof (FIG. 4A), the sensor 31B (FIG. 4B) at the center thereof, and is configured to be able to detect a wall surface and a support pin.

By operating the hand holder 21 (fingers 22) of the transfer robot 20 disposed in the transfer chamber TC, the robot control device 100 causes the fingers 22 to enter the process chamber PC from the transfer chamber TC and further advance inside the process chamber PC.

While the fingers 22 are entering the process chamber PC, both sidewall surfaces are sensed by the sensor device 30 (sensor 31A and 32A), and the lower direction of the advancing direction of the fingers 22 is sensed by the sensor device 30 (sensor 31B). Support pins 90 disposed on both sidewall surfaces and in the process chamber PC are sequentially detected, and positions (coordinates) thereof are calculated.

The robot control device 100 teaches the fingers 22 of the transfer robot 20 to be moved to a target position while the fingers 22 avoid collision with the wall surfaces of the process chamber PC and the support pins on the basis of the positions of the both sidewall surfaces and the support pins acquired through sensing.

### Robot Teaching Method

Next, a method of ascertaining a state of the inside of the process chamber PC by using the sensor device 30 held at the tip of the fingers 22 while causing the hand holder 21 (fingers 22) of the transfer robot 20 to enter the process chamber PC from the transfer chamber TC, and teaching the transfer robot 20 to be moved to a target position will be specifically described in detail.

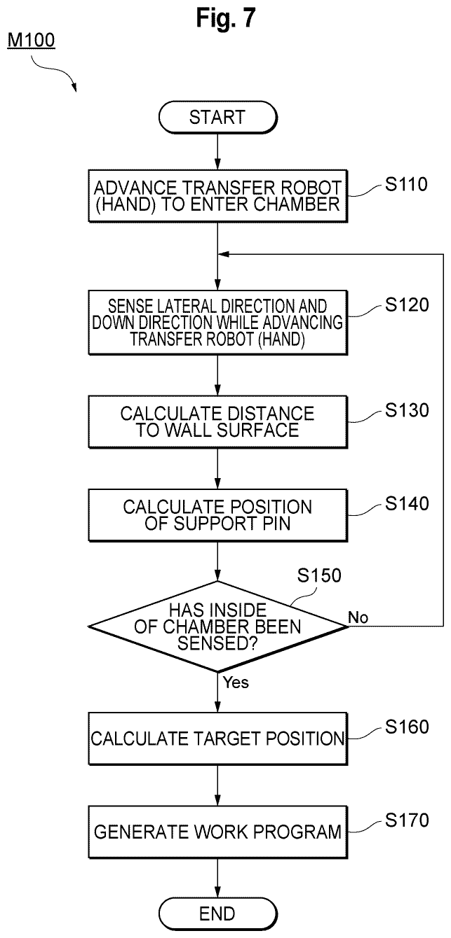

FIG. 7 is a flowchart illustrating a flow of processing of a robot teaching method M100 executed by the robot teaching system 11 used in the flat panel manufacturing system 1 according to the embodiment of the present invention. As illustrated in FIG. 7, the robot teaching method M100 includes steps S110 to S170, and each step is executed by a processor included in the robot control device 100.

In step S110, the robot control unit 110 causes the hand holder 21 (fingers 22) of the transfer robot 20 to enter the process chamber PC from the transfer chamber TC in a state in which the sensor device 30 is held at the tip of the fingers 22.

In step S120, the sensing unit 120 senses the inside of the process chamber PC by using the sensor device 30 held at the tip of the fingers 22 while advancing the fingers 22 inside the process chamber PC. Specifically, the wall surface sensing unit 121 senses both sidewall surface directions by using the two sensors 31A and 32A attached to both ends of the sensor device 30, and the support pin sensing unit 122 senses the lower direction of the advancing direction of the fingers 22 by using the sensor 31B attached to the center of the sensor device 30.

In step S130, the feature point detection unit 130 and the position calculation unit 140 calculate a distance to the wall surface by using each point on the wall surface sensed at each predetermined timing in step S120 as a feature point. A position (coordinates) of the wall surface is calculated.

In step S140, the feature point detection unit 130 and the position calculation unit 140 calculates a position (coordinates) of the support pin detected by sequentially sensing the lower direction of the advancing direction of the fingers 22 in step S120.

Note that steps S130 and S140 may be processed in parallel, or may be processed in reverse order or alternately.

In step S150, the robot control device 100 determines whether the sensing of the inside of the process chamber PC has been completed. If the sensing of the inside of the process chamber PC has been completed (“Yes” in step S150), the flow proceeds to the processing in step S160. If the sensing of the inside of the process chamber PC has not been completed (“No” in step S150), the flow returns to the processing in step S120 and advances the fingers 22 to continue the sensing of the inside of the process chamber PC.

Note that, for example, it may be determined that the sensing of the inside of the process chamber PC is completed when the tip of the fingers 22 reaches the vicinity of the back wall surface of the process chamber PC. On the other hand, it is not always necessary to sense the entire inside of the process chamber PC. For example, it may be determined that the sensing of the inside of the process chamber PC is completed when the TCP reaches a target position.

In step S160, the robot control device 100 calculates a target position on the basis of the position (coordinates) of the wall surface and/or the positions (coordinates) of the support pins calculated in step S130 and/or step S140. For example, the robot control device 100 may set the center of the process chamber PC as the target position.

Here, the target position is calculated in step S160 after the sensing of the inside of the process chamber PC has been completed (“Yes” in step S150), but the target position may be calculated or set before the sensing of the inside of the process chamber PC is completed.

In step S170, the program generation unit 150 generates a work program for operating the transfer robot 20 to be moved to the target position calculated in step S160. For example, in the work program, an operation of the transfer robot 20 including the operation path of the transfer robot 20 is set such that the fingers 22 of the transfer robot 20 reach the target position while avoiding collision with the wall surface and the support pins of the process chamber PC.

As described above, according to the robot teaching system 11, the robot control device 100, and the robot teaching method M100, the robot control unit 110 causes the fingers 22 of the transfer robot 20 to enter the process chamber PC from the transfer chamber TC. The sensing unit 120 senses both sidewall surfaces inside the process chamber PC, the lower direction of the advancing direction, and the like by using the sensor device 30 installed at the tip of the fingers 22, and the feature point detection unit 130 detects a feature point in the process chamber PC. The program generation unit 150 generates a work program for operating the transfer robot 20 to be moved to a target position on the basis of a position of the feature point calculated by the position calculation unit 140. As a result, it is possible to ascertain a state of the inside of the process chamber PC and appropriately generate a work program for moving the transfer robot 20 (TCP) to the target position in the process chamber PC.

In the present embodiment, the situation in which the hand holder 21 (fingers 22) of the transfer robot 20 enters the process chamber PC from the transfer chamber TC has been described as an example, but the present invention is not limited thereto. For example, even in a situation where the hand holder 21 (fingers 22) of the transfer robot 20 enters the load lock chamber LLC from the transfer chamber TC, the present invention can be similarly applied.

The embodiments described above are intended to facilitate understanding of the present invention, and are not intended to limit the present invention. Each element included in the embodiment and the arrangement, material, condition, shape, size, and the like thereof are not limited to those exemplified, and can be appropriately changed. It is possible to partially replace or combine the configurations described in different embodiments.

What is claimed is:

1. A robot teaching system including a plurality of chambers, a transfer robot that transfers a workpiece between the plurality of chambers, and a robot control device that controls an operation of the transfer robot, and used in a flat panel manufacturing system that manufactures a flat panel, the robot teaching system comprising:
feature point detection unit that detects a feature point in a chamber while sensing inside of the chamber by using a sensor installed in a holding portion that holds the workpiece in the transfer robot;
position calculation unit that calculates a position of the feature point; and
program generation unit that generates a work program for operating the transfer robot to be moved to a target position based on the position of the feature point.

2. The robot teaching system according to claim 1, wherein
the feature point includes at least a part of a support pin that supports the workpiece in the chamber.

3. The robot teaching system according to claim 1, wherein
the feature point includes at least a part of a wall surface configuring the chamber.

4. The robot teaching system according to claim 1, wherein
an operation path of the transfer robot is set to avoid a collision in the chamber in the work program.

5. The robot teaching system according to claim 1, further comprising:
mapping unit that maps the position of the feature point in the chamber; and
display unit that displays a result of the mapping.

6. The robot teaching system according to claim 1, further comprising
target position receiving unit that receives a method of setting the target position through a user operation.

7. A robot control device that is used in a flat panel manufacturing system for manufacturing a flat panel and controls an operation of a transfer robot that transfers a workpiece between a plurality of chambers, the robot control device comprising:
feature point detection unit that detects a feature point in a chamber while sensing inside of the chamber by using a sensor installed in a holding portion that holds the workpiece in the transfer robot;
position calculation unit that calculates a position of the feature point; and
program generation unit that generates a work program for operating the transfer robot to be moved to a target position based on the position of the feature point.
